(19) United States
(12) Patent Application Publication
(10) Pub. No.: US 2022/0089044 A1
(43) Pub. Date: Mar. 24, 2022

(54) DEVICE FOR ELECTRICAL CHARGING OF A VEHICLE BATTERY OF AN ELECTRICALLY OPERATED VEHICLE, AND METHOD FOR MANUFACTURING A DEVICE FOR ELECTRICAL CHARGING OF A VEHICLE BATTERY OF AN ELECTRICALLY OPERATED VEHICLE

(71) Applicant: Lisa Draexlmaier GmbH, Vilsbiburg (DE)

(72) Inventors: Andreas ALTMANN, Aholming (DE); Florian MAYER, Seyboldsdorf (DE)

(73) Assignee: Lisa Draexlmaier GmbH, Vilsbiburg (DE)

(21) Appl. No.: 17/476,647

(22) Filed: Sep. 16, 2021

(30) Foreign Application Priority Data
Sep. 21, 2020 (DE) 10 2020 124 513.0

(51) Int. Cl. B60L 53/14; H02J 7/00; H05K 1/18

(52) U.S. Cl. CPC B60L 53/14; H02J 7/0042; H05K 2201/10151; H05K 1/189; H05K 1/181; H02J 7/0047

(57) ABSTRACT

A device for electrical charging of a vehicle battery of an electrically operated vehicle includes at least two electrical contact elements that are configured to guide electrical current and a flexible circuit board that is electrically and mechanically connected to the electrical contact elements. The flexible circuit board is disposed perpendicular to a main extension direction of the electrical contact elements. A method for manufacturing a device for electrical charging of a vehicle battery of an electrically operated vehicle is also provided.

### CROSS-REFERENCE TO RELATED APPLICATIONS

This application claims priority to and the benefit of DE 10 2020 124 513.0, filed on Sep. 21, 2020. The disclosure of the above application is incorporated herein by reference.

### FIELD

The present disclosure relates to a device for electrical charging of a vehicle battery of an electrically operated vehicle and a method for manufacturing a device for electrical charging of a vehicle battery of an electrically operated vehicle.

### BACKGROUND

The statements in this section merely provide background information related to the present disclosure and may not constitute prior art.

During an electrical charging process of an electric vehicle, due to the current- and voltage-transmission heat arises inside an electrical coupling element, such as, for example, a charging jack and a charging plug. Due to the heat energy arising during the current flow, the charging jack and the charging plug can overheat. In order to provide a safe operation of the electrical charging process, the temperature of the current- and voltage-conducting elements of the charging jack and of the charging plug is measured. This can be achieved via a temperature sensor that is connected via cables to the current- and voltage-conducting elements. This requires a high installation expense and a long heat-conduction path. In addition, the temperature sensors require a larger installation space inside the charging plug or the charging jack.

DE 10 2019 114 229 A1 describes a charging plug in particular for an electric vehicle, wherein the charging plug includes a circuit on a circuit board, a component carrier, and at least one contact element oriented transverse to the circuit board, wherein the circuit for the contact element includes a temperature sensor, and the component carrier consists of an electrically insulating heat-conducting material, wherein the temperature sensor is disposed on a front side of the circuit board, which front side is oriented transverse to the contact element, in an edge region of the circuit board, and the component carrier is disposed as electrical insulator and heat-conductor between the contact element and the temperature sensor, wherein the component carrier abuts against the contact element at least in the region of the temperature sensor, and the temperature sensor is disposed in a recess of the component carrier.

### SUMMARY

This section provides a general summary of the disclosure and is not a comprehensive disclosure of its full scope or all of its features.

The present disclosure uses the relatively simple means to provide an improved temperature measuring of electrical contact elements of electrical coupling elements, taking into account the small installation space inside the electrical coupling elements.

One aspect of the present disclosure relates to a device for electrical charging of a vehicle battery of an electrically operated vehicle, comprising at least two electrical contact elements, which are configured to guide electrical currents, and a flexible circuit board that is electrically and mechanically connected to the electrical contact elements, wherein the flexible circuit board is disposed perpendicular to a main extension direction of the electrical contact elements. The electrically operated vehicle can be either a purely electrically operated vehicle or a hybrid vehicle. The device for electrical charging of a vehicle battery can be, for example, a charging jack or a charging plug. Here the electrically operated vehicle can comprise the charging plug. The charging jack can be attached to a vehicle or to a stationary charging station. The device allows the electrical charging both by direct current and by alternating current. Contact pins and corresponding contact jacks serve as electrical contact elements for electrical and mechanical connection between charging plug and charging jack. In order to produce an electrical connection between the charging plug and the charging jack and to start an electrical charging process of the electrically operated vehicle, the contact pins are inserted into the contact jacks in a plug direction as the main extension direction.

The electrical contact elements are configured for an information exchange with the device or as potential equalization, to guide current, and can be disposed in the device in a predetermined arrangement. Any variety of contact elements can be disposed in the device. The electrical contact elements can be disposed, for example, in a receptacle of the device, which receptacle is provided for the electrical contact elements. In order to produce an electrical contact between the electrical contact elements inside the device, a flexible circuit board is attached around the respective electrical contact elements. The flexible circuit board is disposed on the electrical contact elements perpendicular to the plug direction of the electrical contact elements as the main extension direction and can be welded to each individual contact element by ultrasonic welding. All electrical contact elements are electrically connected to one another via the flexible circuit board. The flexible circuit board can consist, for example, of polyimide films and, for example, have a minimum thickness of 0.2 mm. At one end of the flexible circuit board, the flexible circuit board can be connected to a rigid circuit board in order to realize various configurations of devices. Further electronics, for example a temperature sensor, can be disposed on the flexible circuit board.

Due to the arrangement of a flexible circuit board on the electrical contact elements, less space requirement inside the device is required since the flexible circuit board can be installed in a space-saving manner. In addition, the device is weight-saving due to the flexible circuit board.

Furthermore, in a connecting region of the flexible circuit board to the respective electrical contact elements, a temperature sensor is disposed on at least one of the electrical contact elements and configured to measure a temperature of the electrical contact element. Due to the respective electrical contact elements, high charging currents flow with high output voltages, whereby heat also arises inside the electrical contact elements and the device. Due to the applying, in the direct connection region of the flexible circuit board, of the temperature sensor to the respective electrical contact element, the temperature of the electrical contact element can be measured reliably and with minimal arising heat. During a measuring of the temperature of a plurality of electrical contact elements, the respective temperatures of the individual electrical contact elements can be passed on via data transmission to an evaluation unit. The evaluation unit can form the average value of the individual temperatures, and taking into account further influencing factors, determine a temperature of the device. A continuous and controlled temperature monitoring of the electrical contact element, and optionally of the device, can thus be effected via the temperature sensor. In comparison to a conventional circuit board, the flexible circuit board has a smaller mass, whereby a significantly reduced heat discharge arises. The reduced heat discharge of the flexible circuit board contributes to a more precise temperature measuring.

In one form of the present disclosure, each electrical contact element comprises at least one heat-conducting element for increasing the heat-conducting capacity and for maintaining the electrical insulation. The heat-conducting element can be attached to the electrical contact element via attachment elements, for example, plastic clamps. The heat-conducting elements can be attached to all electrical contact elements of the device. In a further form, isolated electrical contact elements can include a heat-conducting element. For example, the electrical contact element can include a variety of heat-conducting elements. It is particularly advantageous if the heat-conducting element is insulating up to a surge voltage of 2.5 kV. The heat-conducting coefficient of the heat-conducting element should be >10W/m*K. The heat-conducting element also serves for maintaining the electrical insulation and the creepage distances.

In a further form, the temperature sensor comprises at least one heat-conducting element for increasing the heat-conducting capacity. Due to the heat-conducting element, the heat of the electrical contact element, which heat is generated by the guided electrical current, is directly guided to the temperature sensor, whereby a more precise measuring of the temperature of the electrical contact element is provided.

Furthermore, each temperature sensor is adhered to the electrical contact elements.

Here the adhesive should have a temperature resistance up to 120° C.

Furthermore, each flexible circuit board is welded to the electrical contact elements. The flexible circuit board can be welded to the electrical contact elements using a welding method, for example, by ultrasonic welding. Here the electrical contact elements are attached in an ultrasonic welding device. Using the sonotrode of the ultrasonic welding device, to which ultrasonic vibrations are transmitted, the flexible circuit board is welded to the electrical contact elements. Here in one form, the flexible circuit board can be welded to each electrical contact element in individual method steps. In another form, the flexible circuit board is welded to all electrical contact elements in a single method step.

A further aspect of the present disclosure relates to a method for manufacturing a device for electrical charging of a vehicle battery of an electrically operated vehicle, comprising a providing of at least two electrical contact elements; a disposing of a flexible circuit board on each of the electrical contact elements, wherein the flexible circuit board is disposed along a main extension direction of the electrical contact elements, and an electrical and mechanical connecting of the flexible circuit board to the electrical contact elements. During the providing, the electrical contact elements can be disposed, for example, in a receptacle of the device. The flexible circuit board is subsequently disposed on the electrical contact elements, and attached to the electrical contact elements, for example, via ultrasonic welding.

In one form, the flexible circuit board can first be disposed on the electrical contact elements and welded to the electrical contact elements via ultrasonic welding. After the flexible circuit board has been connected to the electrical contact elements, the electrical contact elements are inserted into the device with the attached flexible circuit board. Here, the electrical contact elements can be inserted into the receptacle of the device and mechanically connected thereto.

Furthermore, the connecting of the flexible circuit board to the electrical contact elements comprises an attaching of a temperature sensor to the respective electrical contact element in a connecting region of the flexible circuit board to the respective electrical contact element. The temperature sensor can be adhered to the electrical contact element and is mechanically connected to the flexible circuit board.

The temperature sensor can be soldered to the flexible circuit board. For example, the temperature sensor can also be electrically conductively adhered. The temperature sensor can optionally be integrated into the flexible circuit board, wherein a copper path of the flexible circuit board is interrupted, and the temperature sensor is directly applied to the flexible circuit board.

Furthermore, a heat-conducting element is disposed on the temperature sensor and/or on the electrical contact element. The heat-conducting element can be attached to the electrical contact element via attachment elements, such as clips or plastic clamps. The heat-conducting element increases the heat transmission between the electrical contact element and the temperature sensor, whereby a more precise temperature measuring is provided. In addition, the heat-conducting element serves for galvanic isolation and for electrical insulation.

Due to the applying of the flexible circuit board to the electrical contact elements, both an electrical contact of the electrical contact elements to each other and a precise temperature measuring of the respective electrical contact elements are provided, since the temperature sensor is directly attached to the electrical contact element.

In one form, the arrangement of the heat-conducting element between the electrical contact element and the temperature sensor provides directly determined measured values of the temperature, which are detected by the effective heat conduction on the temperature sensor.

Further features, advantages, and details of the present disclosure arise from the following description of one form as well as with reference to the drawings. The features and feature combinations mentioned above in the description, as well as the features and feature combinations shown below in the figure description and/or in the figures alone are usable not only in the combination specified, but also in other combinations or alone without departing from the context of the present disclosure.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a front view of a device for electrical charging of a vehicle battery of an electrically operated vehicle in one form, according to the teaching of the present disclosure; and

FIG. 2 shows a schematic view of a method for manufacturing a device for electrical charging of a vehicle battery of an electrically operated vehicle, according to the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

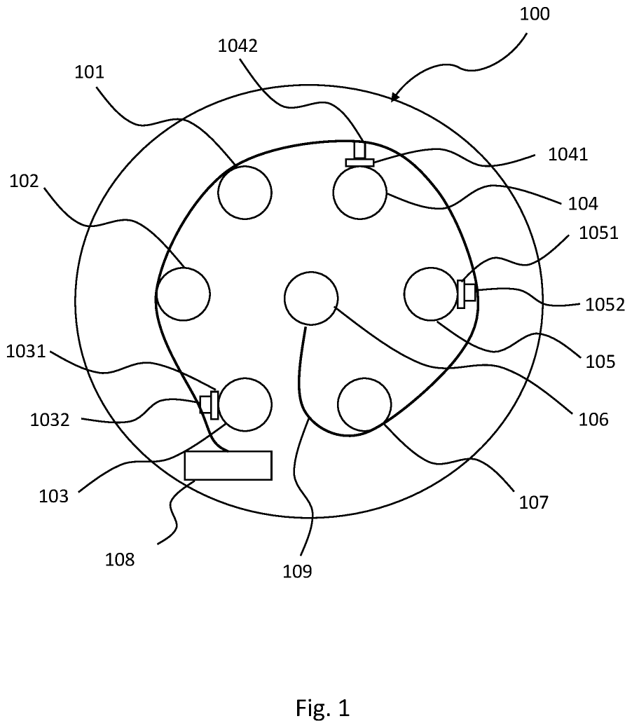

FIG. 1 shows the device for electrical charging of a vehicle battery of an electrically operated vehicle in a front view according one form of the present disclosure. In the one form shown in FIG. 1, seven contact pins 101, 102, 103, 104, 105, 106, 107 are disposed as electrical contact elements on a charging jack 100 as device. For electrical charging of an electrically operated vehicle, the contact pins 101, 102, 103, 104, 105, 106, 107 of the charging jack 100 are inserted in a plug direction as a main extension direction into a corresponding contact jack of a charging plug in order to electrically connect the contact pins 101, 102, 103, 104, 105, 106, 107 to each of the respective corresponding contact jacks. In a further form, the device is a charging plug.

In a further form, any plurality of contact pins 101, 102, 103, 104, 105, 106, 107 can be disposed on the charging jack 100. The contact pins 101, 102, 103, 104, 105, 106, 107 are connected to one another via a flexible circuit board 109. The flexible circuit board 109 can be welded, for example, to each of the individual contact pins 101, 102, 103, 104, 105, 106, 107. On individual contact pins 103, 104, 105, a temperature sensor 1032, 1042, 1052 is disposed, which detects the temperature of the respective contact pins 103, 104, 105. The temperature sensor 1032, 1042, 1052 can be soldered to the flexible circuit board 109 or electrically conductively adhered and can be mechanically connected to the contact pin 103, 104, 105. In one form, the temperature sensor 1032, 1042, 1052 can be adhered with an adhesive to the respective contact pin 103, 104, 105.

The flexible circuit board 109 is disposed perpendicular to a plug direction of the contact pins 101, 102 103, 104, 105, 106, 107 as a main extension direction of the contact pins 101, 102, 103, 104, 105, 106, 107 on the contact pins 101, 102, 103, 104, 105, 106, 107, and electrically and mechanically attached. On the contact pins 101, 102, 106, 107, the flexible circuit board 109 is welded to the contact pins 101, 102, 106, 107 in order to produce a galvanic connection between the contact pins 101, 102, 103, 104, 105, 106, 107. Additional components that produce the galvanic contact between the contact pins 101, 102, 103, 104, 105, 106, 107 and further electronics are thereby omitted. The plug direction is defined as the direction in which the contact pins 101, 102, 103, 104, 105, 106, 107 are inserted into the corresponding contact jacks of a charging plug in order to produce an electrical and mechanical connection between the charging jack 100 and the charging plug.

In addition, heat-conducting elements 1031, 1041, 1051 are disposed on the contact pins 103, 104, 105 between the respective contact pin 103, 104, 105 and the respective temperature sensor 1032, 1042, 1052. The heat-conducting elements 1031, 1041, 1051 are attached to the contact pins 103, 104, 105, for example, via plastic clamps. The heat-conducting elements 1031, 1041, 1051 serve for better heat conduction of the contact pins 103, 104, 105 to the respective temperature sensors 1032, 1042, 1052, whereby an improved measuring of the temperature is provided. Due to the low heat capacity of the flexible circuit board 109, a highly dynamic temperature measuring can additionally be effected.

In addition, the flexible circuit board 109 is connected to a rigid circuit board 108. The rigid circuit board 108 is located inside the charging jack 100. Further electronics can be disposed on the rigid circuit board 108. Using the rigid circuit board 108, individual variants of the charging jack 100 can be configured. For example, with multiple-charging sockets that comprise contact pins 101, 102, 103, 104, 105, 106, 107 in various planes, the flexible circuit board 109 can also be used in order to contact the various planes.

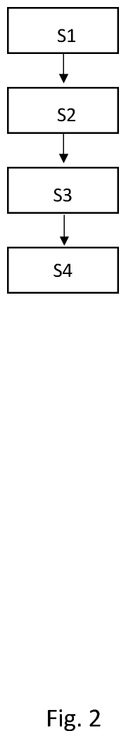

FIG. 2 shows a schematic view of the method for manufacturing a device for electrical charging of a vehicle battery of an electrically operated vehicle.

In a first step S1, the contact pins 101, 102, 103, 104, 105, 106, 107 of the charging jack 100 are provided. The contact pins 101, 102, 103, 104, 105, 106, 107 can be disposed, for example, in a receptacle of the charging jack 100. The contact pins 101, 102, 103, 104, 105, 106, 107 are disposed in a plug direction as a main extension direction, so that the contact pins 103, 104, 105 can be inserted in the plug direction into contact jacks of a charging plug in order to produce an electrical and mechanical connection between charging jack 100 and charging plug.

Subsequently in a second step S2 the flexible circuit board is disposed around the contact pins 101, 102, 103, 104, 105, 106, 107. The flexible circuit board is disposed perpendicular to the plug direction as a main extension direction of the contact pins 101, 102, 103, 104, 105, 106, 107 on the contact pins 101, 102, 103, 104, 105, 106, 107.

In a third step S3, the flexible circuit board is electrically and mechanically connected to the contact pins 101, 102, 103, 104, 105, 106, 107. Here the flexible circuit board can be welded to the contact pins 101, 102, 103, 104, 105, 106, 107. The flexible circuit board can be disposed at least partially around the contact pins 101, 102, 103, 104, 105, 106, 107, and welded to the contact pins 101, 102, 103, 104, 105, 106, 107 using the ultrasonic welding method. For example, also only isolated contact pins 101, 102, 103, 104, 105, 106, 107 can be electrically connected to one another by the flexible circuit board 109.

In one form, the flexible circuit board can first be welded to the contact pins 101, 102, 103, 104, 105, 106, 107 before the contact pins 101, 102, 103, 104, 105, 106, 107 are disposed in the charging jack 100.

In a fourth step S4, the temperature sensors 1032, 1042, 1052 are attached to the respective electrical contact element 103, 104, 105 in a connection region of the flexible circuit board 109 on the respective electrical contact element 103, 104, 105. The temperature sensors 1032, 1042, 1052 can be mechanically attached to the contact elements 103, 104, 105 and soldered to the flexible circuit board 109 or electrically conductively adhered.

In one form, the temperature sensors 1032, 1042, 1052 can be directly introduced into the flexible circuit board 109 by a copper path of the flexible circuit board 109 being interrupted, and the temperature sensors 1032, 1042, 1052 being applied on the flexible circuit board 109, for example, as platinum-chip temperature sensors. Additional components can thereby be saved.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A device for electrical charging of a vehicle battery of an electrically operated vehicle, the device comprising:
at least two electrical contact elements configured to guide electrical current; and
a flexible circuit board electrically and mechanically connected to the electrical contact elements, wherein the flexible circuit board is disposed perpendicular to a main extension direction of the electrical contact elements.

2. The device according to claim 1, wherein in a connection region of the flexible circuit board to the respective electrical contact elements, a temperature sensor is disposed on at least one of the electrical contact elements and configured to detect a temperature of the electrical contact element.

3. The device according to claim 2, wherein each electrical contact element comprises at least one heat-conducting element for increasing heat-conducting capacity.

4. The device according to claim 2, wherein the temperature sensor comprises at least one heat-conducting element for increasing heat-conducting capacity.

5. The device according to claim 2, wherein the temperature sensor is respectively adhered to the electrical contact elements.

6. The device according to claim 1, wherein the flexible circuit board is welded to each of the electrical contact elements.

7. A method for manufacturing a device for electrical charging of a vehicle battery of an electrically operated vehicle, the method comprising:
providing of at least two electrical contact elements;
disposing a flexible circuit board on each of the electrical contact elements, wherein the flexible circuit board is disposed along a main extension direction of the electrical contact elements; and
electrically and mechanically connecting the flexible circuit board to the electrical contact elements.

8. The method according to claim 7, wherein the connecting of the flexible circuit board to the electrical contact elements comprises attaching a temperature sensor to the respective electrical contact element in a connection region of the flexible circuit board to the respective electrical contact element.

9. The method according to claim 8, wherein a heat-conducting element is disposed on the temperature sensor.

10. The method according to claim 8, wherein a heat-conducting element is disposed on the electrical contact element.
